(19) United States
(12) Patent Application Publication
(10) Pub. No.: US 2025/0370344 A1
(43) Pub. Date: Dec. 4, 2025

(54) RESIST UNDERLAYER COMPOSITIONS AND METHODS OF FORMING PATTERNS USING THE COMPOSITIONS

(71) Applicant: SAMSUNG SDI CO., LTD., Yongin-si (KR)

(72) Inventors: Jaemin LEE, Yongin-si (KR); Hwayoung JIN, Yongin-si (KR); Soojeung KIM, Yongin-si (KR); Seongjin KIM, Yongin-si (KR); Sungwoo JUNG, Yongin-si (KR); Jungin MUN, Yongin-si (KR)

(21) Appl. No.: 19/221,766

(22) Filed: May 29, 2025

(30) Foreign Application Priority Data
Jun. 4, 2024 (KR) 10-2024-0073313

(51) Int. Cl. G03F 7/11

(52) U.S. Cl. CPC G03F 7/11

(57) ABSTRACT

A resist underlayer composition, a method of forming a pattern using the resist underlayer composition are provided. The resist underlayer composition includes solvent and a polymer including a structural unit represented by Chemical Formula 1, a structural unit represented by Chemical Formula 2, and a structural unit represented by Chemical Formula 3.

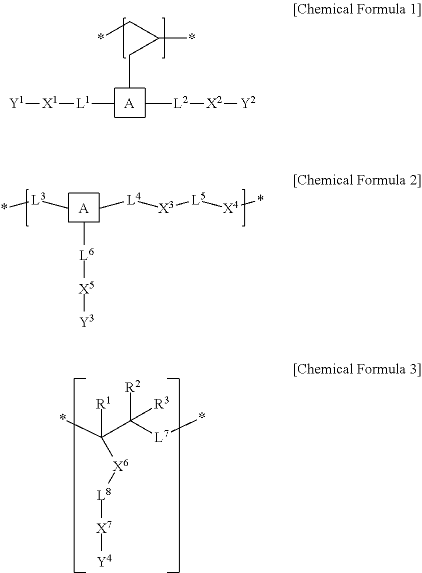

### CROSS-REFERENCE TO RELATED APPLICATION

This application claims priority to and the benefit of Korean Patent Application No. 10-2024-0073313 filed in the Korean Intellectual Property Office on Jun. 4, 2024, the entire contents of which are incorporated herein by reference.

### BACKGROUND

### 1. Field

This disclosure relates to resist underlayer compositions and methods of forming patterns using the compositions.

### 2. Description of the Related Art

The semiconductor industry has developed ultra-fine techniques having patterns of several to several tens of nanometer size. Such ultrafine techniques need effective lithographic techniques.

A lithographic technique is a processing method that includes coating a photoresist film on a semiconductor substrate such as a silicon wafer to form a thin film, irradiating the photoresist film with activating radiation such as ultraviolet rays through a mask pattern on which the device pattern is drawn, developing the resultant to obtain a photoresist pattern, and etching the substrate using the photoresist pattern as a protective layer to form a fine pattern corresponding to the pattern on the surface of the substrate.

As semiconductor patterns become increasingly more fine, thicknesses of photoresist layers are required to be thin, and, accordingly, thicknesses of resist underlayers are also required to be thin. But a thin resist underlayer should not collapse the photoresist pattern, should have good adhesion to the photoresist, and should be formed with a uniform thickness. In addition, the resist underlayer should have a high refractive index and low extinction coefficient for the light used in photolithography and a faster etch rate than the photoresist layer.

### SUMMARY

The resist underlayer composition according to some example embodiments provides a resist underlayer with improved patterning performance and energy efficiency by preventing pattern collapse of the resist even in a fine patterning process and improves sensitivity to an exposure light source.

Some example embodiments provide a method of forming a pattern using the resist underlayer composition.

A underlayer composition according to some example embodiments includes a polymer including at least one of a structural unit represented by Chemical Formula 1, a structural unit represented by Chemical Formula 2, and a structural unit represented by Chemical Formula 3, and the polymer should also include a solvent:

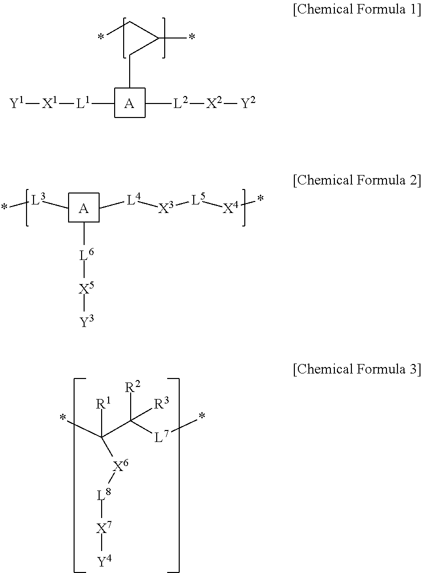

### In Chemical Formula 1 to Chemical Formula 3:

A is a heterocyclic group including a nitrogen atom in the ring,
L¹ to L⁸ are each independently a single bond, a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C2 to C20 heterocycloalkylene group, a substituted or unsubstituted C6 to C20 arylene group, or a combination thereof,
X¹ to X⁷ are each independently a single bond, —O—, —S—, —S(═O)—, —S(═O)₂—, —C(═O)—, —(CO)O—, —O(CO)O—, —C(═O)NH—, —NR^{a}— (wherein, R^{a} is hydrogen, deuterium, or a C1 to C10 alkyl group), or a combination thereof,
Y¹ and Y² are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C2 to C20 heterocycloalkyl group, a substituted or unsubstituted C6 to C20 aryl group, a group represented by Chemical Formula 4, or a combination thereof, provided that at least one of Y¹ and Y² is a group represented by Chemical Formula 4,
Y³ and Y⁴ are each independently a group represented by Chemical Formula 4,
R¹ to R³ are each independently hydrogen, deuterium, or a substituted or unsubstituted C1 to C10 alkyl group, and
* is a linking point:

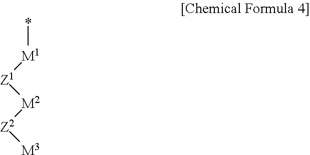

wherein, in Chemical Formula 4:
M¹ is a single bond, a substituted or unsubstituted C1 to C20 alkylene group, substituted or unsubstituted C2 to C20 alkenylene group, —O—, —NH—, or a combination thereof,
Z¹ and Z² are each independently —C(═O)— or —C(OH)—,
M² is a single bond, a double bond, *—C(R^{c})═* (wherein, R^{c} is hydrogen, deuterium, or a C1 to C5 alkyl group, and * is a linking point with Z¹ or Z²), or a substituted or unsubstituted C1 to C3 alkylene group,
M³ is a hydroxy group, a substituted or unsubstituted C1 to C20 alkyl group, a substituted or unsubstituted C2 to C20 alkenyl group, or a substituted or unsubstituted C6 to C20 aryl group,
M¹ and M³ or M² and M³ are optionally linked to each other to form a ring, and
* is a linking point.

A in Chemical Formula 1 and Chemical Formula 2 may be represented by any one of Chemical Formula A-1 to Chemical Formula A-5:

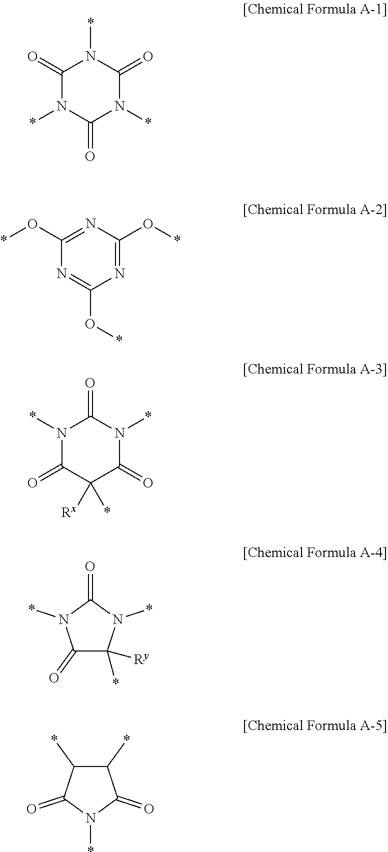

### In Chemical Formula A-3 and Chemical Formula A-4:

R^{x} and R^{y} are each independently hydrogen, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof, and
* is a linking point.

In Chemical Formula 1, A may be Chemical Formula A-1, L¹ and L² may each independently be a single bond, or a substituted or unsubstituted C1 to C10 alkylene group, and X¹ and X² may each independently be a single bond:

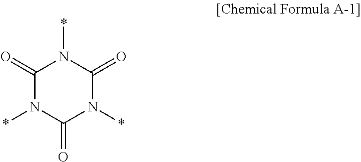 [SMILES: *n1c(=O)n(*)c(=O)n(*)c1=O]

In Chemical Formula 3, L⁷ and L⁸ may each independently be a single bond, or a substituted or unsubstituted C1 to C10 alkylene group, X⁶ and X⁷ may each independently be a single bond, or —(CO)O—, and R¹ to R³ may each independently be hydrogen, deuterium, or a substituted or unsubstituted C1 to C5 alkyl group.

The polymer may further include a structural unit represented by Chemical Formula 5, or a structural unit represented by Chemical Formula 6:

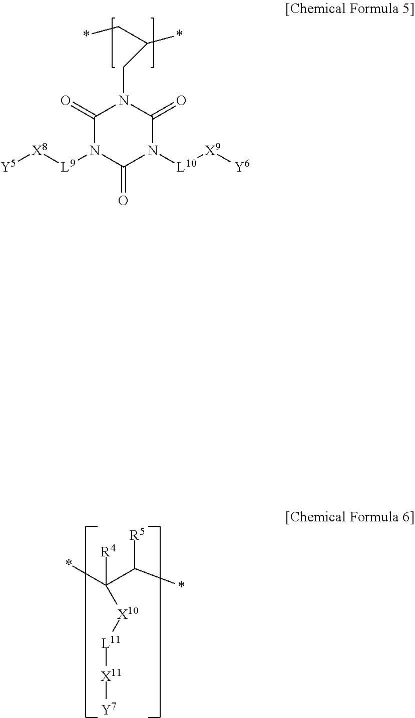

### In Chemical Formula 5 and In Chemical Formula 6:

L⁹ to L¹¹ are each independently a single bond, a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C2 to C20 heterocycloalkylene group, a substituted or unsubstituted C6 to C20 arylene group, or a combination thereof,
X⁸ to X¹¹ are each independently a single bond, —O—, —S—, —S(═O)—, —S(═O)₂—, —C(═O)—, —(CO)O—, —O(CO)O—, —C(═O)NH—, —NR^{b}— (wherein, R^{b} is hydrogen, deuterium, or a C1 to C10 alkyl group), or a combination thereof,
Y⁵ to Y⁷ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C2 to C20 heterocycloalkyl group, or a substituted or unsubstituted C6 to C20 aryl group,
R⁴ and R⁵ are each independently hydrogen, deuterium, or a substituted or unsubstituted C1 to C10 alkyl group, and
* is a linking point.

In Chemical Formula 5, L⁹ and L¹⁰ may each independently be a single bond, or a substituted or unsubstituted C1 to C10 alkylene group, X⁸ and X⁹ may each independently be a single bond, and Y⁵ and Y⁶ may each independently be a hydroxy group, a substituted or unsubstituted C1 to C10 alkyl group, or a substituted or unsubstituted C2 to C10 alkenyl group.

In Chemical Formula 6, L¹¹ may be a single bond, a substituted or unsubstituted C1 to C10 alkylene group, X¹⁰ and X¹¹ may each independently be a single bond, or —(CO)O—, and Y⁷ may be a hydroxy group, a substituted or unsubstituted C1 to C10 alkyl group, a substituted or unsubstituted C2 to C20 heterocycloalkyl group, or a substituted or unsubstituted C6 to C20 aryl group.

The polymer may include any one or more of the structural units represented by Chemical Formula 1-1, Chemical Formula 2-1, and Chemical Formula 3-1 to Chemical Formula 3-8:

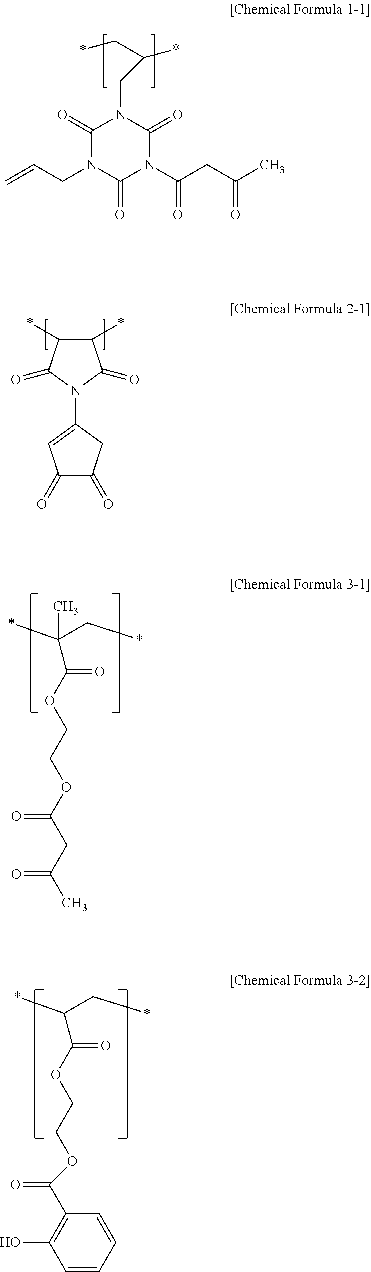

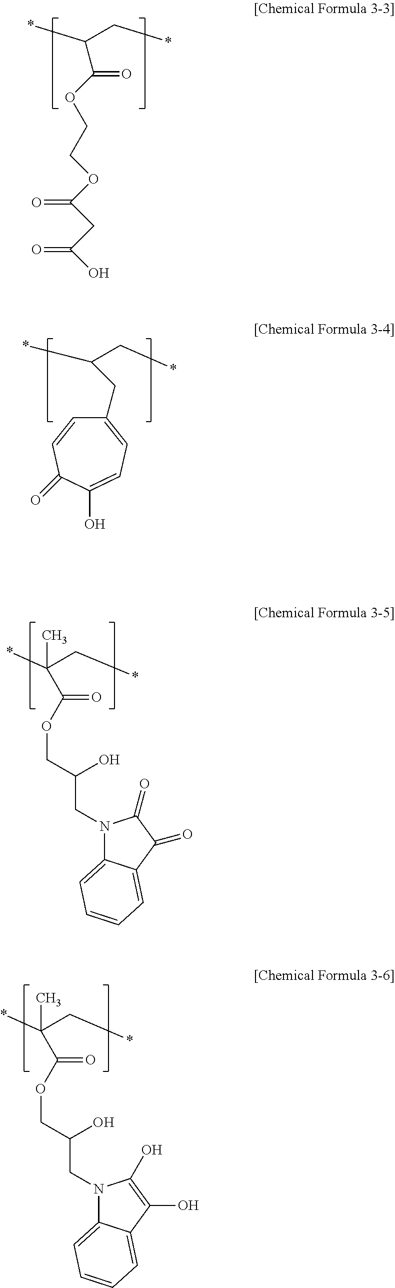

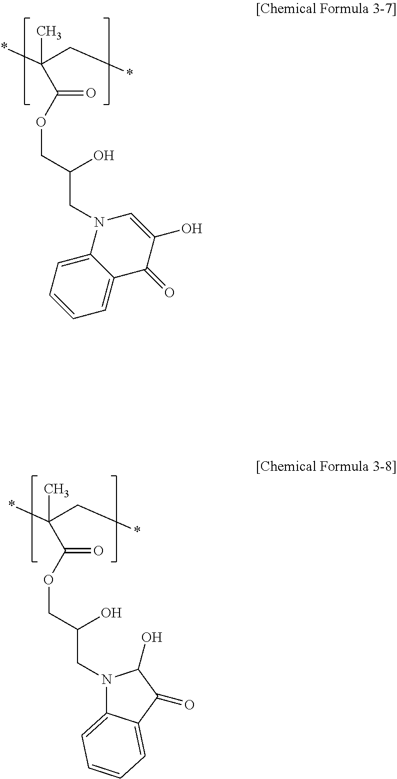

A weight average molecular weight of the polymer may be about 1,000 g/mol to about 300,000 g/mol.

The polymer may be included in an amount of about 0.1 wt % to about 50 wt % based on a total weight of the resist underlayer composition.

The composition may further include one or more polymers selected from an acrylic resin, an epoxy resin, a novolac-based resin, a glycoluril-based resin, and a melamine-based resin.

The composition may further include additives such as a surfactant, a thermal acid generator, a photoacid generator, a plasticizer, or a combination thereof.

According to some example embodiments, a method of forming a pattern includes forming an etching target layer on a substrate, forming a resist underlayer by applying the resist underlayer composition according to embodiments of the disclosure, forming a photoresist pattern on the resist underlayer, and sequentially etching the resist underlayer and the etching target layer using the photoresist pattern as an etching mask.

The resist underlayer composition according to some example embodiments can provide a resist underlayer that prevents pattern collapse even in a fine patterning process and has improved sensitivity to an exposure light source, thereby improving patterning performance and energy efficiency.

### BRIEF DESCRIPTION OF THE DRAWINGS

FIG. 1 is a cross-sectional view illustrating a method of forming a pattern using a resist underlayer composition according to example embodiments of the disclosure.

### DETAILED DESCRIPTION

Example embodiments of the present disclosure will hereinafter be described in more detail, and may be easily practiced by a person skilled in the art. However, this disclosure may be embodied in many different forms and is not limited to the example embodiments set forth herein.

In the drawings, the thickness of layers, films, panels, regions, etc., are exaggerated for clarity and like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

As used herein, when a definition is not otherwise provided, “substituted” refers to replacement of a hydrogen atom of a compound by a substituent selected from deuterium, a halogen (F, Br, Cl, or I), a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C30 heterocyclic group, and a combination thereof.

In addition, two adjacent substituents of the substituted halogen atom (F, Br, Cl, or I), hydroxy group, nitro group, cyano group, amino group, azido group, amidino group, hydrazino group, hydrazono group, carbonyl group, carbamyl group, thiol group, ester group, carboxyl group or salt thereof, sulfonic acid group or salt thereof, phosphoric acid or salt thereof, C1 to C30 alkyl group, C2 to C30 alkenyl group, C2 to C30 alkynyl group, C6 to C30 aryl group, C7 to C30 arylalkyl group, C1 to C30 alkoxy group, C1 to C20 heteroalkyl group, C3 to C20 heteroarylalkyl group, C3 to C30 cycloalkyl group, C3 to C15 cycloalkenyl group, C6 to C15 cycloalkynyl group, or C2 to C30 heterocyclic group may be fused with each other to form a ring.

As used herein, “heterocyclic group” includes a heteroaryl group, and a cyclic group including at least one heteroatom selected from N, O, S, P, and Si instead of carbon (C) of a cyclic compound such as an aryl group, a cycloalkyl group, a fused ring thereof, or a combination thereof. When the heterocyclic group is a fused ring, each or the entire ring of the heterocyclic group may include at least one heteroatom.

More specifically, a substituted or unsubstituted aryl group and/or a substituted or unsubstituted heterocyclic group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiphenyl group, a substituted or unsubstituted carbazolyl group, a pyridoindolyl group, a benzopyridooxazinyl group, a benzopyridothiazinyl group, a 9,9-dimethyl-9,10-dihydroacridinyl group, a combination thereof, or a combined fused ring of the foregoing groups, but the present disclosure is not limited thereto.

As used herein, when specific definition is not otherwise provided, the term “combination” refers to mixing or copolymerization.

Additionally, as used herein, “polymer” may include both oligomers and polymers.

Unless otherwise specified in the present specification, the weight average molecular weight is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

In addition, unless otherwise defined in the specification, a “*” indicates a linking point of a structural unit or a moiety of a polymer.

In the semiconductor industry, there is a constant demand to reduce the size of chips. In order to meet this trend, a line width of the resist patterned in lithography technology can be reduced to a level of several tens of nanometers, and the pattern formed in this way is used to transfer the pattern to a substrate below the pattern by using an etching process on the substrate. However, as the pattern size of the resist becomes smaller, a height (aspect ratio) of the resist that can withstand the line width is limited, and the resists may thereby not have sufficient durability in the etching step. Thus, a resist underlayer has been used to compensate for this when a thin resist material is used, when the substrate to be etched is thick, or when a deep pattern is required.

The resist underlayer should be thinner as the thickness of the resist becomes thinner, and the photoresist pattern should not collapse even if the resist underlayer is thin. The resist underlayer should therefore have excellent adhesion to the photoresist. In addition, in forming a thin resist underlayer, coating uniformity of the resist underlayer composition and flatness of the resist underlayer produced therefrom should be improved, and sensitivity to the exposure light source should be improved to improve pattern formability and energy efficiency.

A underlayer composition according to some example embodiments includes a solvent and polymer including at least one of a structural unit represented by Chemical Formula 1, a structural unit represented by Chemical Formula 2, and a structural unit represented by Chemical Formula 3:

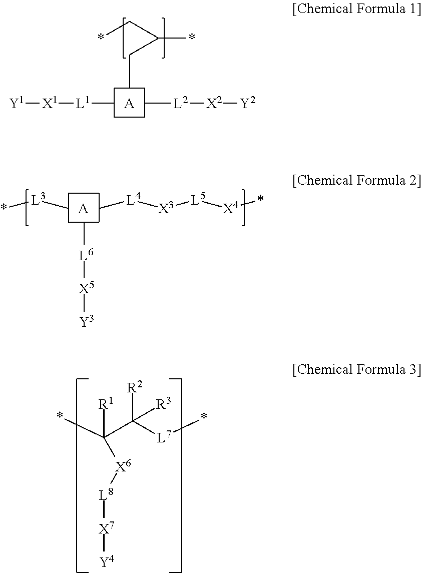

In Chemical Formula 1 to Chemical Formula 3:
A is a heterocyclic group including a nitrogen atom in the ring,
L¹ to L⁸ are each independently a single bond, a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C2 to C20 heterocycloalkylene group, a substituted or unsubstituted C6 to C20 arylene group, or a combination thereof,
X¹ to X⁷ are each independently a single bond, —O—, —S—, —S(═O)—, —S(═O)₂—, —C(═O)—, —(CO)O—, —O(CO)O—, —C(═O)NH—, —NR^{a}— (wherein, R^{a} is hydrogen, deuterium, or a C1 to C10 alkyl group), or a combination thereof,
Y¹ and Y² are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C2 to C20 heterocycloalkyl group, a substituted or unsubstituted C6 to C20 aryl group, a group represented by Chemical Formula 4, or a combination thereof, provided that at least one of Y¹ and Y² is a group represented by Chemical Formula 4,
Y³ and Y⁴ are each independently a group represented by Chemical Formula 4,
R¹ to R³ are each independently hydrogen, deuterium, or a substituted or unsubstituted C1 to C10 alkyl group, and
* is a linking point:

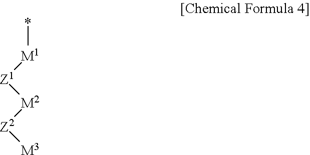

### In Chemical Formula 4:

M¹ is a single bond, substituted or unsubstituted C1 to C20 alkylene group, a substituted or unsubstituted C2 to C20 alkenylene group, —O—, —NH—, or a combination thereof,
Z¹ and Z² are each independently —C(═O)— or —C(OH)—,
M² is a single bond, a double bond, *—C(R^{c})═* (where R^{c} is hydrogen, deuterium, or a C1 to C5 alkyl group, and * is a linking point with Z¹ or Z²), or a substituted or unsubstituted C1 to C3 alkylene group,
M³ is a hydroxy group, a substituted or unsubstituted C1 to C20 alkyl group, a substituted or unsubstituted C2 to C20 alkenyl group, a substituted or unsubstituted C6 to C20 aryl group, or a combination thereof,
M¹ and M³ or M² and M³ are optionally linked to each other to form a ring, and
* is a linking point.

In the underlayer composition according to some example embodiments, the structural unit represented by Chemical Formula 1 and the structural unit represented by Chemical Formula 2 include a hetero ring including a nitrogen atom in the ring, so that so that the polymer including these structural units may have a sp²-sp² bond between polymers. This allows the polymer to have high electron density. If underlayer composition includes a polymer with high electron density, the underlayer composition can form a dense ultra-thin film. Additionally, the high electron density of the polymer can improve light absorption efficiency when the resist underlayer composition is exposed to light. Further, by including the heterocyclic skeleton, the etch selectivity is improved, and energy efficiency can be improved when forming patterns after exposure using high-energy rays such as EUV (Extreme ultraviolet; wavelength 13.5 nm) and E-Beam (electron beam).

The polymer included in the composition may include a structural unit having a group represented by Chemical Formula 4 at a terminal end. Chemical Formula 4 includes two or more —(C═O)— or —C(OH)— at adjacent positions to form a coordination bond with an inorganic material in the photoresist. Thus, adhesion between the resist underlayer and the photoresist film formed from the composition can be improved.

A in Chemical Formula 1 and Chemical Formula 2 may be represented by any one of Chemical Formula A-1 to Chemical Formula A-5:

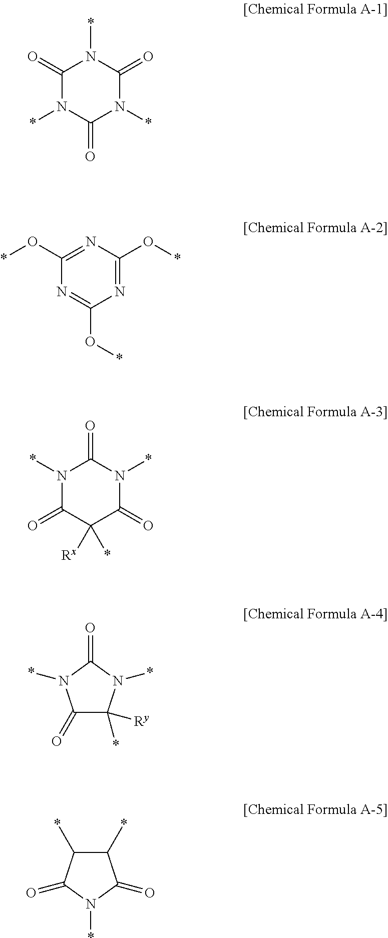

### In Chemical Formula A-3 and Chemical Formula A-4:

R^{x} and R^{y} are each independently hydrogen, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof, and
* is a linking point.

In some example embodiments, A of Chemical Formula 1 is Chemical Formula A-1, but the present disclosure is not limited thereto.

L¹ and L² of Chemical Formula 1 are each independently, for example, a single bond, a substituted or unsubstituted C1 to C10 heteroalkylene group, or a substituted or unsubstituted C1 to C10 alkylene group, for example, a single bond, or a substituted or unsubstituted C1 to C10 alkylene group, or for example, a single bond, or a substituted or unsubstituted C1 to C5 alkylene group, but is not limited thereto.

In Chemical Formula 1, X¹ and X² are each independently a single bond, —O—, —C(═O)—, or —(CO)O—, for example, a single bond, but the present disclosure is not limited thereto.

In Chemical Formula 1, Y¹ and Y² are each independently a hydroxy group, a substituted or unsubstituted C1 to C10 alkyl group, a substituted or unsubstituted C2 to C10 alkenyl group, a substituted or unsubstituted C3 to C20 cycloalkyl group, or the group represented by Chemical Formula 4, for example, a hydroxy group, a substituted or unsubstituted C1 to C10 alkyl group, a substituted or unsubstituted C2 to C10 alkenyl group, or the group represented by Chemical Formula 4, or for example, a substituted or unsubstituted C2 to C10 alkenyl group, but the present disclosure is not limited thereto. In the above, at least one of Y¹ and Y² may be a group represented by Chemical Formula 4.

In some example embodiments, A in Chemical Formula 2 is, for example, Chemical Formula A-1 or Chemical Formula A-5, but the present disclosure is not limited thereto. L³ to L⁶ are each independently a single bond, a substituted or unsubstituted C1 to C10 alkylene group, or a substituted or unsubstituted C1 to C10 heteroalkylene group, for example, a single bond, or a substituted or unsubstituted C1 to C10 alkylene group, or for example, a single bond, or a substituted or unsubstituted C1 to C5 alkylene group, but the present disclosure is not limited thereto. X³ to X⁵ are each independently a single bond, —O—, —S—, —C(═O)—, —(CO)O—, or —O(CO)O—, for example, a single bond, —O—, —C(═O)—, or —(CO)O—, or for example, a single bond, but the present disclosure is not limited thereto. Y³ is the group represented by Chemical Formula 4.

In some example embodiments, L⁷ in Chemical Formula 3 is a single bond, or a substituted or unsubstituted C1 to C10 alkylene group, for example, a single bond, but the present disclosure is not limited thereto. L⁸ is each independently a single bond, a substituted or unsubstituted C1 to C10 alkylene group, or a substituted or unsubstituted C2 to C10 alkenylene group, for example, a single bond, or a substituted or unsubstituted C1 to C10 alkylene group, for example, a single bond, or a substituted C1 to C10 alkylene group, or for example, a single bond, or a C1 to C5 alkylene group substituted with a hydroxy group, but the present disclosure is not limited thereto.

In Chemical Formula 3, X⁶ and X⁷ are each independently a single bond, —O—, —C(═O)—, or —(CO)O—, for example a single bond, or —(CO)O—, but the present disclosure is not limited to these.

In Chemical Formula 3, R¹ to R³ is hydrogen, deuterium, or a substituted or unsubstituted C1 to C5 alkyl group, for example, hydrogen, a methyl group, or an ethyl group, but the present disclosure not limited thereto.

In some example embodiments, M¹ of Chemical Formula 4 may be a single bond, a substituted or unsubstituted C1 to C10 alkylene group, a substituted or unsubstituted C2 to C10 alkenylene group, —O—, —NH—, or a combination thereof, for example, a single bond, a substituted or unsubstituted C1 to C5 alkylene group, a substituted or unsubstituted C2 to C5 alkenylene group, —O—, —NH—, or a combination thereof, for example, a substituted or unsubstituted C1 to C5 alkylene group, for example, —NH—, for example, a combination of —O— and a C1 to C5 alkylene group, or for example, a combination of —O— and a C2 to C5 alkenylene group, but the present disclosure is not limited thereto.

In Chemical Formula 4, Z¹ and Z² may each independently be —C(═O)— or —C(OH)—. For example, Z¹ and Z² may each be —C(═O)—, for example, Z¹ and Z² may each be —C(OH)—, or for example, one of Z¹ and Z² may be —C(═O)— and the other may be —C(OH)—.

In Chemical Formula 4, M² may be a single bond, a double bond, *—C(R^{c})═*(wherein, R^{c} is hydrogen, deuterium, or a C1 to C5 alkyl group), or a substituted or unsubstituted C1 to C3 alkylene group, for example, a single bond, double bond, *—CH═*, *—C(CH₃)═*, or a substituted or unsubstituted methylene group, or for example, a single bond, double bond, *—CH═*, or a substituted or unsubstituted methylene group, but the present disclosure is not limited thereto. In *—C(R^{c})═*, the “*” is a linking point with Z¹ or Z².

If M² has more carbon atoms than the above options, a distance between Z¹ and Z² is far, making it difficult to effectively form a coordination bond with the inorganic material in the photoresist, and the adhesion of the resist underlayer to the photoresist film is not great. But if M² is a single bond, a double bond, *—C(R^{c})═*, or a substituted or unsubstituted C1 to C3 alkylene group, the adhesion between the resist underlayer made from the resist underlayer composition and the photoresist film can be effectively increased.

In Chemical Formula 4, M³ may be a hydroxy group, a substituted or unsubstituted C1 to C20 alkyl group, a substituted or unsubstituted C2 to C20 alkenyl group, or a substituted or unsubstituted C6 to C20 aryl group, for example, a hydroxy group, a substituted or unsubstituted C1 to C10 alkyl group, a substituted or unsubstituted C2 to C10 alkenyl group, or a substituted or unsubstituted C6 to C10 aryl group, or for example, a hydroxy group, a substituted or unsubstituted C1 to C5 alkyl group, a substituted or unsubstituted C2 to C5 alkenyl group, or a phenyl group, but the present disclosure is not limited thereto.

M¹ and M³, or M² and M³ of Chemical Formula 4 may each be independently connected to each other to form a ring. That is, in Chemical Formula 4, M¹ and M³ may be optionally linked with each other to form a ring, or M² and M³ may be optionally linked with each other to form a ring. For example, M¹ and M³ may each independently be present, M¹ and M³ may be linked to each other to form a ring, and M² and M³ may each independently be present, and M² and M³ may be linked to each other to form a ring.

In some example embodiments, the polymer may further include a structural unit represented by Chemical Formula 5, or a structural unit represented by Chemical Formula 6:

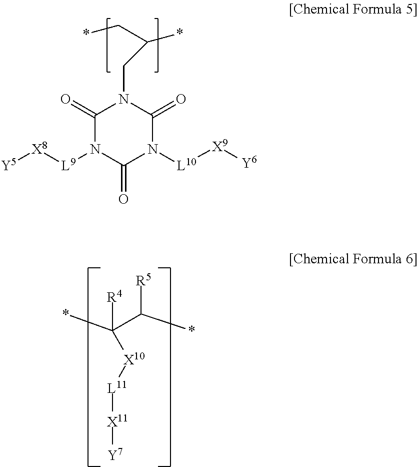

### In Chemical Formula 5 and In Chemical Formula 6:

L⁹ to L¹¹ are each independently a single bond, a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C2 to C20 heterocycloalkylene group, a substituted or unsubstituted C6 to C20 arylene group, or a combination thereof,
X⁸ to X¹¹ are each independently a single bond, —O—, —S—, —S(═O)—, —S(═O)₂—, —C(═O)—, —(CO)O—, —O(CO)O—, —C(═O)NH—, —NR^{b}— (wherein, R^{b} is hydrogen, deuterium, or a C1 to C10 alkyl group), or a combination thereof,
Y⁵ to Y⁷ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C2 to C20 heterocycloalkyl group, or a substituted or unsubstituted C6 to C20 aryl group,
R⁴ and R⁵ are each independently hydrogen, deuterium, or a substituted or unsubstituted C1 to C10 alkyl group, and
* is a linking point.

In some example embodiments, in Chemical Formula 5, L⁹ and L¹⁰ may each independently be a single bond, a substituted or unsubstituted C1 to C10 alkylene group, a substituted or unsubstituted C2 to C10 alkenylene group, for example, a single bond, or a substituted or unsubstituted C1 to C10 alkylene group, or for example, a substituted or unsubstituted C1 to C5 alkylene group, but the present disclosure is not limited thereto.

In Chemical Formula 5, X⁸ and X⁹ may each independently be a single bond, —O—, —C(═O)—, —(CO)O—, —O(CO)O—, or a combination thereof, for example, single bond, —O—, —C(═O)—, —(CO)O—, or a combination thereof, or for example, a single bond, but the present disclosure is not limited thereto.

In Chemical Formula 5, Y⁵ and Y⁶ may each independently be a hydroxy group, a substituted or unsubstituted C1 to C10 alkyl group, a substituted or unsubstituted C2 to C10 alkenyl group, or a substituted or unsubstituted C2 to C20 heterocycloalkyl group, for example, a hydroxy group, a substituted or unsubstituted C1 to C10 alkyl group, or a substituted or unsubstituted C2 to C10 alkenyl group, or for example, a hydroxy group, or a substituted or unsubstituted C2 to C5 alkenyl group, but the present disclosure is not limited thereto.

In some example embodiments, in Chemical Formula 6, L¹¹ may be a single bond, a substituted or unsubstituted C1 to C10 alkylene group, a substituted or unsubstituted C2 to C10 alkenylene group, or a substituted or unsubstituted C6 to C14 arylene group, for example, a single bond, a substituted or unsubstituted C1 to C10 alkylene group, or a substituted or unsubstituted C6 to C10 arylene group, for example, a single bond, a substituted or unsubstituted C1 to C5 alkylene group, or a substituted or unsubstituted phenylene group, but the present disclosure is not limited thereto.

In Chemical Formula 6, X¹⁰ and X¹¹ may each independently be a single bond, —O—, —C(═O)—, —(CO)O—, —O(CO)O—, or a combination thereof, for example, a a single bond, or —(CO)O—, but the present disclosure is not limited thereto.

In Chemical Formula 6, Y⁷ may be a hydroxy group, a substituted or unsubstituted C1 to C10 alkyl group, a substituted or unsubstituted C2 to C10 alkenyl group, a substituted or unsubstituted C2 to C20 heterocycloalkyl group, or a substituted or unsubstituted C6 to C20 aryl group, for example, a hydroxy group, a substituted or unsubstituted C1 to C10 alkyl group, a substituted or unsubstituted C2 to C10 heterocycloalkyl group, or a substituted or unsubstituted C6 to C10 aryl group, or for example, a hydroxy group, an epoxy group, a substituted or unsubstituted phenyl group, but the present disclosure is not limited thereto.

In some example embodiments, the polymer includes any one or more of the structural units represented by Chemical Formula 1-1, Chemical Formula 2-1, and Chemical Formula 3-1 to Chemical Formula 3-8:

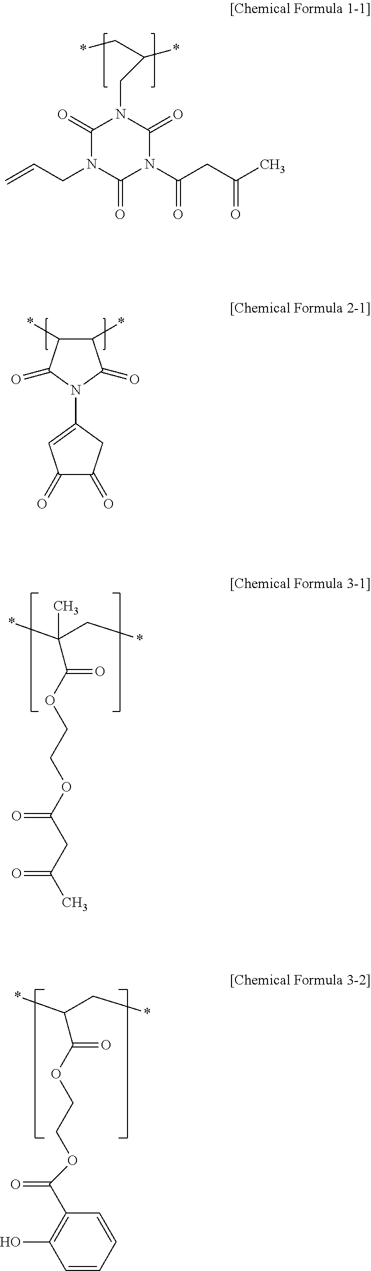

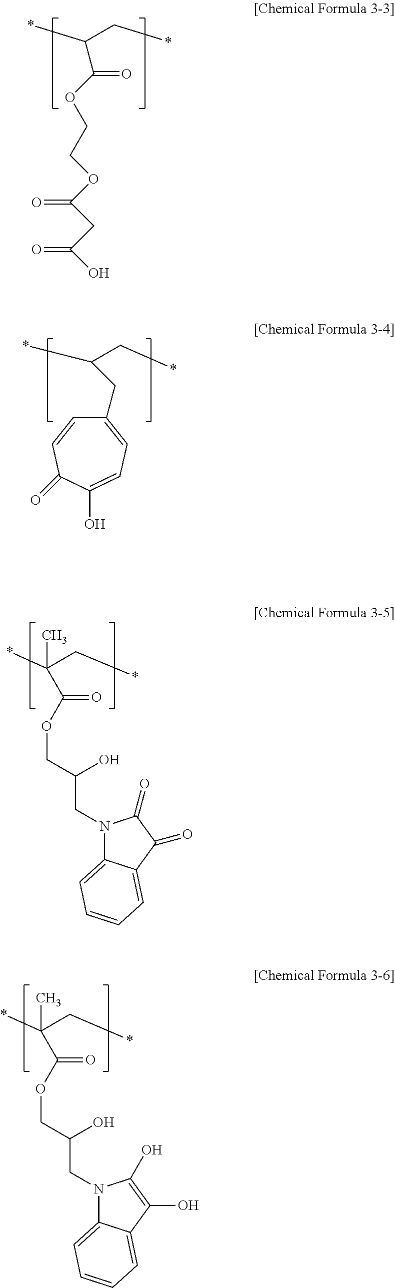

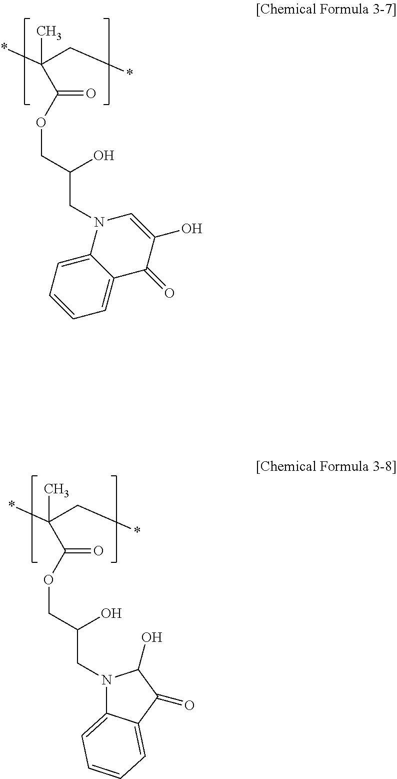

The polymer may have a weight average molecular weight of about 1,000 g/mol to about 300,000 g/mol, More specifically, the polymer may have a weight average molecular weight of about 3,000 g/mol to about 200,000 g/mol, about 3,000 g/mol to about 100,000 g/mol, about 3,000 g/mol to about 90,000 g/mol, about 3,000 g/mol to about 70,000 g/mol, about 3,000 g/mol to about 60,000 g/mol, about 3,000 g/mol to about 50,000 g/mol, about 5,000 g/mol to about 50,000 g/mol, or about 5,000 g/mol to about 30,000 g/mol, but the present disclosure is not limited thereto. By having a weight average molecular weight within the above ranges, carbon content and solubility in the solvent of the resist underlayer composition including the polymer may be adjusted.

The polymer may be included in an amount of about 0.1 wt % to about 50 wt % based on a total weight of the resist underlayer composition. More specifically, the polymer may be included in an amount of about 0.1 wt % to about 40 wt %, about 0.1 wt % to about 30 wt %, about 0.1 wt % to about 20 wt %, or about 0.2 wt % to about 20 wt % based on a total weight of the resist underlayer composition, but the present disclosure is not limited thereto. By including the polymer within the above ranges in the composition, the thickness, surface roughness, and a degree of planarization of the resist underlayer may be adjusted.

The resist underlayer composition according to some example embodiments may include a solvent. The solvent is not particularly limited as long as it has sufficient solubility and/or dispersibility for the polymer and compound according to some example embodiments. The solvent may be, for example, propylene glycol, propylene glycol diacetate, methoxypropanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methyl 2-hydroxyisobutyrate, acetylacetone, ethyl 3-ethoxypropionate, or a combination thereof.

The resist underlayer composition according to some example embodiments may further include one or more polymers selected from an acrylic resin, an epoxy resin, a novolac-based resin, a glycoluril-based resin, and a melamine-based resin, in addition to the polymer, solvent, but the present disclosure is not limited thereto.

The resist underlayer composition according to some example embodiments may further include an additive such as a surfactant, a thermal acid generator, a plasticizer, or a combination thereof.

The surfactant may be used to improve coating defects caused by an increase in a solid content when forming the resist underlayer. The surfactant may be, for example, an alkylbenzenesulfonate salt, an alkylpyridinium salt, polyethylene glycol, a quaternary ammonium salt, or the like, but the present disclosure is not limited thereto.

The thermal acid generator may be an acidic compound such as p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalene carbonic acid, or/and benzointosylate, 2-nitrobenzyltosylate, and other organic sulfonic acid alkylesters may be used, but the present disclosure is not limited thereto.

The plasticizer is not particularly limited, and a variety of known plasticizers may be used. Examples of a plasticizer may include low molecular compounds such as phthalic acid esters, adipic acid esters, phosphoric acid esters, trimellitic acid esters, citric acid esters, and the like, polyether compounds, polyester-based compounds, polyacetal compounds, and the like.

The additive may be included in an amount of about 0.0001 to about 40 parts by weight based on 100 parts by weight of the resist underlayer composition. Within such a range, solubility may be improved while optical properties of the resist underlayer composition are not changed.

According to example embodiments of the present disclosure, a resist underlayer manufactured using the aforementioned resist underlayer composition is provided. The resist underlayer may be formed by coating the aforementioned resist underlayer composition on, for example, a substrate and then curing through a heat treatment process.

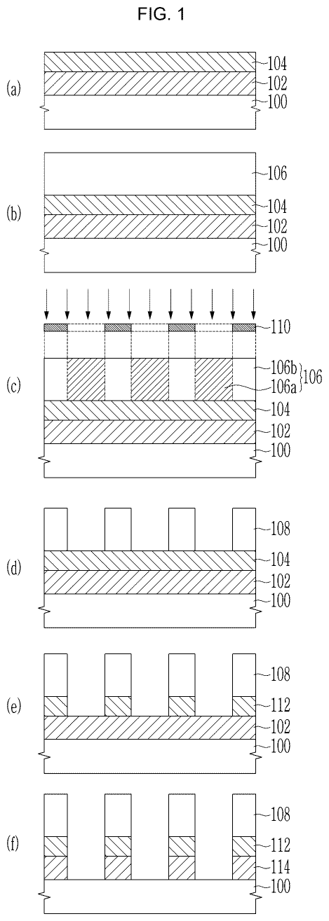

Hereinafter, a method of forming a pattern using the aforementioned resist underlayer composition is described with reference to FIG. 1. FIG. 1 is a cross-sectional view illustrating a method of forming a pattern using the resist underlayer composition according to the present disclosure.

Referring to FIG. 1 (a), an etching target is prepared. The etching target may be a thin film 102 formed on a semiconductor substrate 100. An entire surface of the thin film 102 is washed to remove impurities and the like remaining thereon. The thin film 102 may be, for example, a silicon nitride layer, a polysilicon layer, or a silicon oxide layer.

Subsequently, the aforementioned resist underlayer composition is coated on the surface of the cleaned thin film 102 by a spin coating method. Then, the coated composition is dried and baked to form a resist underlayer 104 on the thin film 102. The baking may be performed at about 100° C. to about 500° C., for example, about 100° C. to about 300° C. The resist underlayer composition is described above in detail and thus will be omitted.

Referring to FIG. 1 (b), a photoresist film 106 is formed by coating a photoresist on the resist underlayer 104.

Examples of the photoresist are a positive-type photoresist including a naphthoquinonediazide compound and a novolac resin, a chemically-amplified positive photoresist including an acid generator capable of dissociating acid through exposure, a compound decomposed under presence of the acid and having increased dissolubility in an alkali aqueous solution, and an alkali soluble resin, a chemically-amplified positive-type photoresist including an alkali-soluble resin capable of applying a resin increasing dissolubility in an alkali aqueous solution, and the like. But the present disclosure is not limited to such examples.

Next, a substrate 100 having the photoresist film 106 is primarily baked. The primary baking may be performed at about 90° C. to about 120° C.

Referring to FIG. 1 (c), the photoresist film 106 may be selectively exposed. Exposure of the photoresist film 106 may be, for example, performed by positioning an exposure mask having a predetermined pattern on a mask stage of an exposure apparatus and aligning the exposure mask 110 with the photoresist film 106. Subsequently, radiating light is directed to the exposure mask 110 such that a predetermined region of the photoresist film 106 formed on the substrate 100 selectively receives and reacts with light passing by the exposure 110. The light used during the exposure may include short wavelength light such as an i-line having a wavelength of 365 nm, a KrF excimer laser having a wavelength of 248 nm, and an ArF excimer laser having a wavelength of 193 nm. In addition, EUV (extreme ultraviolet) having a wavelength of 13.5 nm corresponding to extreme ultraviolet light may be used.

The photoresist film of the exposed region 106a may be relatively hydrophilicity compared with the photoresist film of the unexposed region 106b. Accordingly, the exposed region 106a and non-exposed region 106b of the photoresist film may have different solubility each other.

Subsequently, the substrate 100 is secondarily baked. The secondary baking may be performed at about 90° C. to about 150° C. The exposed region of the photoresist film becomes easily dissoluble with a predetermined solvent due to the secondary baking.

Referring to FIG. 1 (d), specifically, the photoresist film 106a corresponding to the exposed region is dissolved and then removed using tetramethyl ammonium hydroxide (TMAH), etc., and thereby the photoresist film 106b remaining after development forms the photoresist pattern 108.

Subsequently, the resist underlayer 104 is etched using the photoresist pattern 108 as an etch mask. An organic film pattern 112 as shown in FIG. 1 (e) is formed by the etching process. The etching may be, for example, dry etching using etching gas, and the etching gas may be for example CHF₃, CF₄, Cl₂, O₂, and mixtures thereof. As described above, since the resist underlayer formed by the resist underlayer composition according to the embodiment has a fast etch rate, a smooth etching process may be performed in a short time.

Referring to FIG. 1 (f), the photoresist pattern 108 is applied as an etching mask to etch the exposed thin film 102. As a result, the thin film is formed into a thin film pattern 114. In the exposure process, a thin film pattern 114 formed by an exposure process performed using a short wavelength light source such as an i-line (a wavelength of 365 nm), a KrF excimer laser (a wavelength of 248 nm), and an ArF excimer laser (a wavelength of 193 nm) may have a width of tens to hundreds of nm, and the thin film pattern 114 formed by the exposure process performed using the EUV light source may have a width of less than or equal to about 20 nm.

Hereinafter, the present disclosure is described in more detail through examples of synthesis of the polymer and preparation of a resist underlayer composition including the same. However, the present disclosure is not limited to the following examples.

### Synthesis of Polymers

### Synthesis Example 1

7.5 g of (2-acetoacetoxy)ethyl methacrylate (TCI), 4.9 g of glycidyl methacrylate (TCI), 4.8 g of dimethyl 2,2′-azobis(2-methylpropionate) (V-601; TCI) and 64 g of propylene glycol methyl ether acetate (PGMEA) were added to a 500 ml three-necked round flask to prepare a reaction solution and a condenser was connected. The reaction proceeded by heating the reaction solution at 90° C. for 1 hour, and then the reaction solution was cooled to room temperature. Then, the reaction solution was added dropwise while stirring in a beaker including 450 g of heptane to generate gum, which was then dissolved in 90 g of PGMEA. Finally, a polymer composed of structural units represented by Chemical Formula 3-1 and Chemical Formula 6-2 was obtained. The polymer has a molecular weight of 4,000 g/mol.

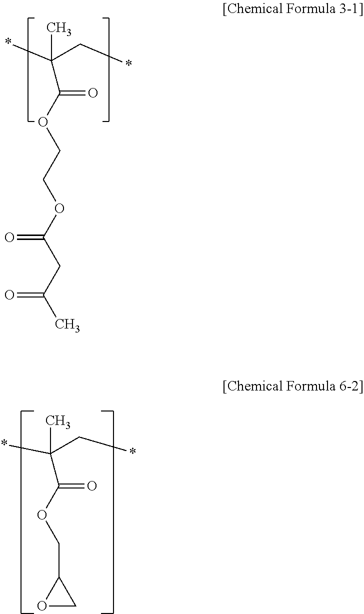

### Synthesis Example 2

1.46 g of glycidyl methacrylate (TCI), 1.81 g of 4-vinylphenyl acetate (TCI), 2.43 g of benzoic acid, 2-hydroxy, 2-[(1-oxo-2-propenyl)oxy]ethyl ester, 1.06 g of dimethyl 2,2′-azobis(2-methylpropionate) (V-601; TCI) and 22 g of propylene glycol methyl ether acetate (PGMEA) were added to a 100 ml two-necked round flask to prepare a reaction solution and a condenser was connected.

The reaction proceeded by heating the reaction solution at 90° C. for 3 hours, and then the reaction solution was cooled to room temperature. Then, the reaction solution was added dropwise while stirring in a beaker including 450 g of toluene to generate gum, which was then dissolved in 90 g of PGMEA. Finally, a polymer composed of structural units represented by Chemical Formula 3-2, Chemical Formula 6-2, and Chemical Formula 6-3 was obtained. The polymer had a molecular weight of 5,000 g/mol.

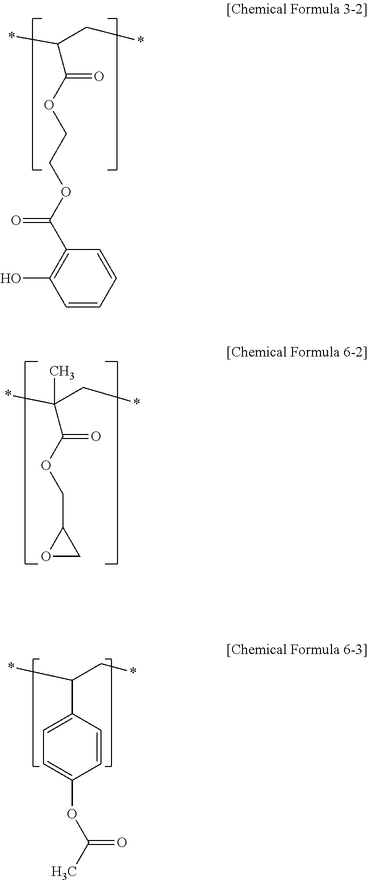

### Synthesis Example 3

5.86 g of 2-hydroxyethyl methacrylate (TCI), 9.1 g of 1-[2-[(1-oxo-2-propen-1-yl)oxy]ethyl]propanedioate (HongKong Chem), 3.1 g of dimethyl 2,2′-azobis(2-methylpropionate) (V-601; TCI), and 35 g of propylene glycol methyl ether acetate (PGMEA) were added to a 500 ml three-necked round flask, and a condenser was connected. The reaction proceeded by heating the reaction solution at 90° C. for 2.5 hours, and then the reaction solution was cooled to room temperature. Then, the reaction solution was added dropwise while stirring in a beaker including 450 g of heptane to generate gum, which was then dissolved in 90 g of PGMEA. Finally, a polymer composed of structural units represented by Chemical Formula 3-3 and Chemical Formula 6-4 was obtained. The polymer had a molecular weight of 6,500 g/mol.

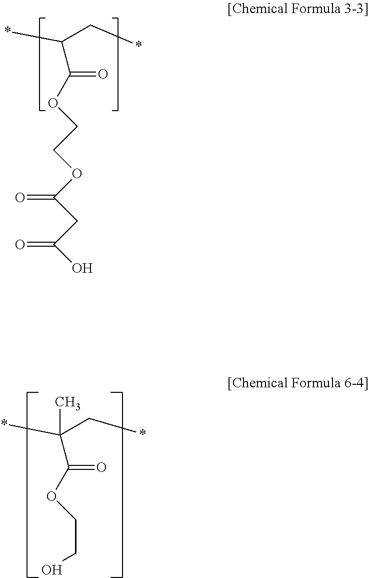

### Synthesis Example 4

6.49 g of 2-hydroxy-5-(2-propen-1-yl)-2,4,6-cycloheptatrien-1-one (Aurora), 4.9 g of glycidyl methacrylate (TCI), 4.8 g of dimethyl 2,2′-azobis(2-methylpropionate) (V-601; TCI), and 64 g of propylene glycol methyl ether acetate (PGMEA) were added to a 200 ml two-necked round flask to prepare a reaction solution and a condenser was connected. The reaction solution was heated at 80° C. for 2 hours, and the reaction solution was added dropwise while stirring in a beaker including 450 g of heptane to generate gum, which was then dissolved in 90 g of PGMEA. Finally, a polymer composed of structural units represented by Chemical Formula 3-4 and Chemical Formula 6-2 was obtained. The polymer had a molecular weight of 5,000 g/mol.

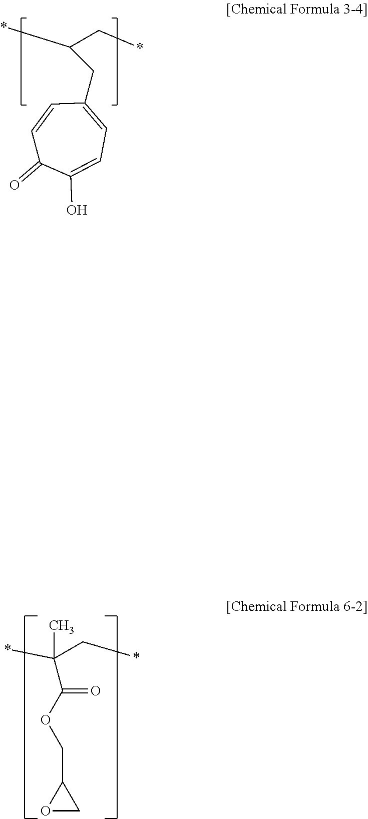

### Synthesis Example 5

21.3 g of glycidyl methacrylate (TCI), 5.1 g of dimethyl 2,2′-azobis(2-methylpropionate) (V-601; TCI), and 50 g of propylene glycol methyl ether acetate (PGMEA) were added to a 250 ml two-necked round flask to prepare a reaction solution and a condenser was connected. The reaction solution was heated at 90° C. for 1 hour and the reaction solution was added dropwise while stirring in a beaker including 450 g of heptane to generate gum, which was then dissolved in 100 g of PGMEA to obtain a polymer composed of a structural unit represented by Chemical Formula 6-2.

5.4 g of the polymer, 0.7 g of Isatin (TCI), 0.04 g of pyridine, 0.011 g of dibutylhydroxytoluene (BHT), and 7.55 g of DMF were added to a 100 ml two-necked round flask, and a condenser was connected. The reaction solution was heated at 100° C. for 1 hour and the reaction solution was added dropwise while stirring in a beaker including 450 g of heptane to generate gum, which was then dissolved in 100 g of PGMEA. Finally, a polymer composed of structural units represented by Chemical Formula 6-2 and Chemical Formula 3-5 was obtained. The polymer had a molecular weight of 8,000 g/mol.

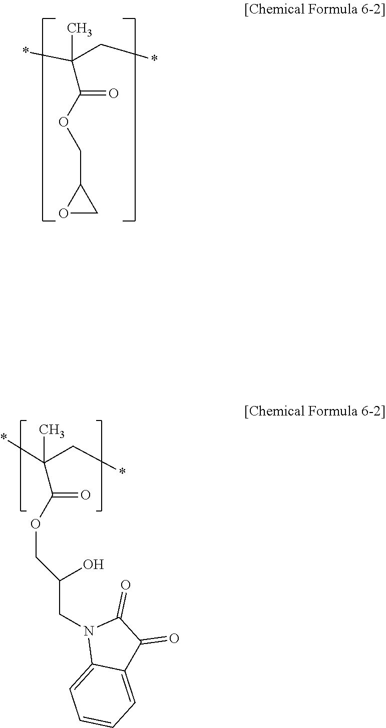

### Synthesis Example 6

21.3 g of glycidyl methacrylate (TCI), 5.1 g of dimethyl 2,2′-azobis(2-methylpropionate) (V-601; TCI), and 50 g of propylene glycol methyl ether acetate (PGMEA) were added to a 250 ml two-necked round flask to prepare a reaction solution and a condenser was connected. The reaction solution was heated at 90° C. for 1 hour and the reaction solution was added dropwise while stirring in a beaker including 450 g of heptane to generate gum, which was then dissolved in 100 g of PGMEA to obtain a polymer composed of a structural unit represented by Chemical Formula 6-2.

5.4 g of the polymer, 0.62 g of 1H-Indole-2,3-diol (AURORA), 0.04 g of pyridine, 0.011 g of BHT, and 7.55 g of DMF were added to a 100 ml two-necked round flask and a condenser was connected. The reaction solution was heated at 100° C. for 1 hour and the reaction solution was added dropwise while stirring in a beaker including 450 g of heptane to generate gum, which was then dissolved in 100 g of PGMEA. Finally, a polymer composed of structural units represented by Chemical Formula 6-2 and Chemical Formula 3-6 was obtained. The polymer had a molecular weight of 8,000 g/mol.

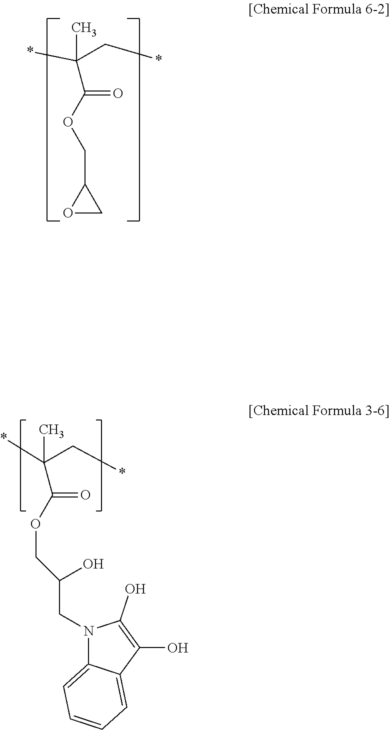

### Synthesis Example 7

21.3 g of glycidyl methacrylate (TCI), 5.1 g of dimethyl 2,2′-azobis(2-methylpropionate) (V-601; TCI), and 50 g of propylene glycol methyl ether acetate (PGMEA) were added to a 250 ml two-necked round flask to prepare a reaction solution and a condenser was connected. The reaction solution was heated at 90° C. for 1 hour and the reaction solution was added dropwise while stirring in a beaker including 450 g of heptane to generate gum, which was then dissolved in 100 g of PGMEA to obtain a polymer composed of a structural unit represented by Chemical Formula 6-2.

5.4 g of the polymer, 0.68 g of 3-hydroxy-4(1H)-quinolinone (Aurora), 0.04 g of pyridine, 0.011 g of BHT, and 7.55 g of DMF are added to a 100 ml two-necked round flask and a condenser was connected. The reaction solution was heated at 100° C. for 1 hour and the reaction solution was added dropwise while stirring in a beaker including 450 g of heptane to generate gum, which was then dissolved in 100 g of PGMEA. Finally, a polymer composed of structural units represented by Chemical Formula 6-2 and Chemical Formula 3-7 was obtained. The polymer had a molecular weight of 8,000 g/mol.

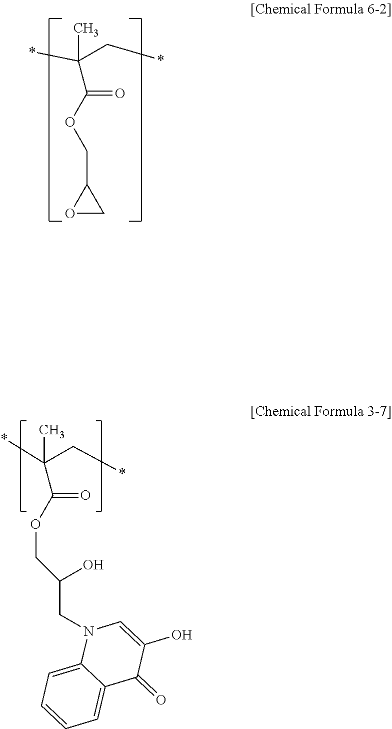

### Synthesis Example 8

21.3 g of glycidyl methacrylate (TCI), 5.1 g of dimethyl 2,2′-azobis(2-methylpropionate) (V-601; TCI), and 50 g of propylene glycol methyl ether acetate (PGMEA) were added to a 250 ml two-necked round flask to prepare a reaction solution and a condenser was connected. The reaction solution was heated at 90° C. for 1 hour and the reaction solution was added dropwise while stirring in a beaker including 450 g of heptane to generate gum, which was then dissolved in 100 g of PGMEA to obtain a polymer composed of a structural unit represented by Chemical Formula 6-2.

5.4 g of the polymer, 0.7 g of 1,2-dihydro-2-hydroxy-3H-indol-3-one (ACCEL), 0.04 g of pyridine, 0.011 g of BHT, and 7.55 g of DMF were added to a 100 ml two-necked round flask to prepare a reaction solution and a condenser was connected. The reaction solution was heated at 100° C. for 1 hour and the reaction solution was added dropwise while stirring in a beaker including 450 g of heptane to generate gum, which was then dissolved in 100 g of PGMEA. Finally, a polymer composed of structural units represented by Chemical Formula 6-2 and Chemical Formula 3-8 is obtained. The polymer had a molecular weight of 8,000 g/mol.

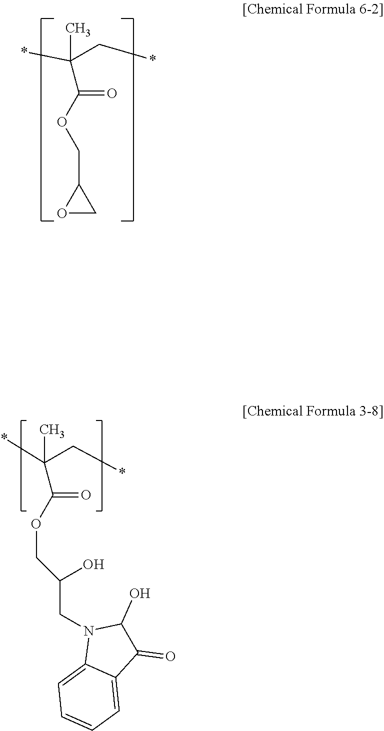

### Comparative Synthesis Example 1

2.8 g of glycidyl methacrylate (TCI), 2.1 g of dimethyl 2,2′-azobis(2-methylpropionate (V-601; TCI), and 7 g of propylene glycol methyl ether acetate (PGMEA) were added to a 500 ml three-necked round flask to prepare a reaction solution and a condenser was connected. The reaction proceeded by heating the reaction solution at 85° C. for 2 hours, and then the reaction solution was cooled to room temperature. Then, the reaction solution was added dropwise while stirring in a beaker including 450 g of heptane to generate gum, which was then dissolved in 90 g of PGMEA. Finally, a polymer composed of structural units represented by Chemical Formula 6-2 is obtained. The polymer had a molecular weight of 3,000 g/mol.

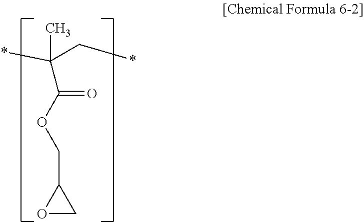

### Preparation of Resist Underlayer Compositions

### Examples 1 to 8 and Comparative Example 1

1.2 g of each polymer obtained in Synthesis Examples 1 to 8 and Comparative Synthesis Example 1, 0.4 g of PL1174 (crosslinking agent), and 0.04 g of ammonium triflate (AOTf) were mixed with 15 g of propylene glycol monomethyl ether, completely dissolved, and diluted with an additional solvent to prepare each resist underlayer composition according to Examples 1 to 8 and Comparative Example 1, with each example and comparative example including 0.45 wt % of polymer based on total weight.

### Evaluation 1: Evaluation of Exposure Characteristics

The compositions prepared in Examples 1 to 8 and Comparative Example 1 were spin-on coated and then heat treated on a hot plate at 205° C. for 60 seconds to form a resist underlayer with a thickness of 50 Å. Subsequently, on the underlayers, a photoresist solution was spin-on coated and then heat-treated on a hot plate at 110° C. for 1 minutes to form a photoresist layer. The photoresist layer was exposed to light in the range of 200 μC/cm² to 2000 μC/cm² by using an e-beam light exposer (Elionix, Inc.) and then heat-treated at 150° C. for 60 seconds. Subsequently, the photoresist layer was developed with a 2.38 mass % TMAH aqueous solution and rinsed with pure water for 15 seconds to form a line and space (US) photoresist pattern of 50 nm. The photoresist pattern was evaluated with respect to an optimal exposure dose.

### Evaluation 2 Evaluation of Line Width Roughness (LWR)

Each of the compositions according to Examples 1 to 8 and Comparative Example 1 was spin-on coated and heat-treated on a hot plate at 205° C. for 60 seconds to form a 50 Å-thick resist underlayer. Subsequently, on the underlayers, a photoresist solution was spin-on coated and then heat-treated on a hot plate at 110° C. for 1 minutes to form a photoresist layer. The resist layer was exposed using an e-beam exposure machine (manufactured by Elionix, acceleration voltage 100 keV) under the conditions of a line width of 30 nm and a space between lines of 30 nm. Subsequently, the exposed resist layer was heat-treated at 95° C. for 60 seconds, developed with a 2.38 wt % tetramethyl ammonium hydroxide (TMAH) aqueous solution for 60 seconds, and rinsed with pure water for 15 seconds to form a resist pattern.

Pattern collapse was examined using a scanning electron microscope (SEM)S-9260 (manufactured by Hitachi). As shown in Table 1, cases where pattern collapse was observed are indicated as O, and cases where pattern collapse was not observed are indicated as X.

LWR (Line Width Roughness) was examined with a scanning electron microscope (SEM)S-9260 (manufactured by Hitachi) on a pattern formed with a width of 30 nm, and the distance from the reference line where the edge should be was measured for a 2 μm range of the edge in the longitudinal direction of the pattern. The results are as shown in Table 1, with the smaller the line width roughness (LWR) values being better.

The exposure doses and LWR according to the examples and the comparative examples were converted into a ratio based on the exposure dose or LWR of Comparative Example 1 as reference, and the results are shown in Table 1. The smaller the exposure dose and line width roughness (LWR) value, the better the pattern formation and sensitivity.

In the table, Exposure dose (or LWR) (%)=(Exposure dose (or LWR) according to each Experimental Example—Exposure dose (or LWR) according to Comparative Example 1)/Exposure dose (or LWR) according to Comparative Example 1×100.

TABLE 1

| | Exposure dose | Pattern collapse | LWR |
|---|---|---|---|
| | (Eop, %) | or not | (nm) |
| Example 1 | −4.5% | X | −5.4% |
| Example 2 | −1.2% | X | −2.2% |
| Example 3 | −4.2% | X | −5.1% |
| Example 4 | −2.5% | X | −2.8% |
| Example 5 | −5.5% | X | −4.7% |
| Example 6 | −5.2% | X | −4.8% |
| Example 7 | −4.5% | X | −4.8% |
| Example 8 | −5.2% | X | −5.0% |
| Comparative | Ref. | ◯ | Ref. |
| Example 1 | | | |

### Example 1

Referring to Table 1, the resist underlayers according to Examples 1 to 8 have superior fine pattern (50 nm US) formability and sensitivity compared to Comparative Example 1. Additionally, in the case of the resist underlayers according to Examples 1 to 8, the LWR is lower than that of Comparative Example 1, indicating that the pattern is more uniform.

Herein, certain embodiments of the present disclosure have been described and illustrated. However, as is apparent to a person with ordinary skill in the art, the present disclosure is not limited to the embodiments as expressly described and may be variously modified and transformed without departing from the spirit and scope of the present disclosure. Accordingly, modified or transformed embodiments as such may be understood from the described technical ideas and aspects of the present disclosure.

<Description of symbols>

| | |
|---|---|
| 100: substrate | 102: thin film |
| 104: resist underlayer | 106: photoresist film |
| 106a: exposed region | 106b: unexposed region |
| 108: photoresist pattern | 110: mask |
| 112: organic film pattern | 114: thin film pattern |

What is claimed is:

1. A resist underlayer composition comprising
a solvent; and
a polymer comprising at least one of a structural unit represented by Chemical Formula 1, a structural unit represented by Chemical Formula 2, and a structural unit represented by Chemical Formula 3: 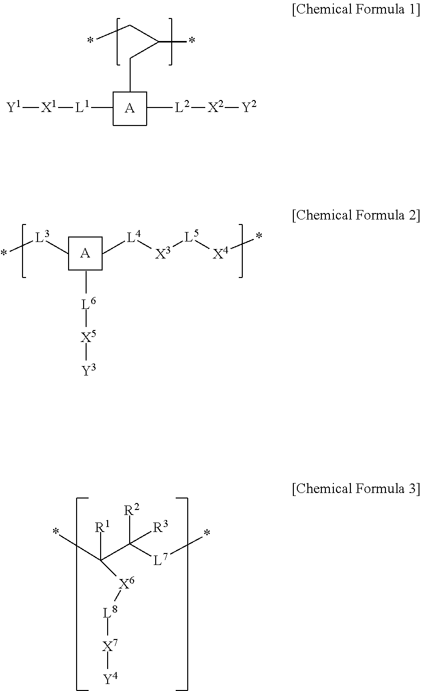
wherein, in Chemical Formula 1 to Chemical Formula 3:
A is a heterocyclic group including a nitrogen atom in the ring,
L¹ to L⁸ are each independently a single bond, a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C2 to C20 heterocycloalkylene group, a substituted or unsubstituted C6 to C20 arylene group, or a combination thereof,
X¹ to X⁷ are each independently a single bond, —O—, —S—, —S(═O)—, —S(═O)₂—, —C(═O)—, —(CO)O—, —O(CO)O—, —C(═O)NH—, —NR^{a}— (wherein, R^{a} is hydrogen, deuterium, or a C1 to C10 alkyl group), or a combination thereof,
Y¹ and Y² are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C2 to C20 heterocycloalkyl group, a substituted or unsubstituted C6 to C20 aryl group, a group represented by Chemical Formula 4, or a combination thereof, provided that at least one of Y¹ and Y² is a group represented by Chemical Formula 4,
Y³ and Y⁴ are each independently a group represented by Chemical Formula 4,
R¹ to R³ are each independently hydrogen, deuterium, or a substituted or unsubstituted C1 to C10 alkyl group, and
* is a linking point: 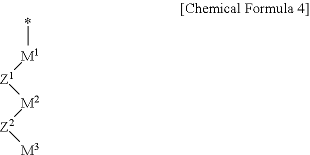
wherein, in Chemical Formula 4,
M¹ is a single bond, substituted or unsubstituted C1 to C20 alkylene group, a substituted or unsubstituted C2 to C20 alkenylene group, —O—, —NH—, or a combination thereof,
Z¹ and Z² are each independently —C(═O)— or —C(OH)—,
M² is a single bond, a double bond, *—C(R^{c})═*, or a substituted or unsubstituted C1 to C3 alkylene group, with R^{c} being hydrogen, deuterium, or a C1 to C5 alkyl group, and * is a linking point with Z¹ or Z²
M³ is a hydroxy group, a substituted or unsubstituted C1 to C20 alkyl group, a substituted or unsubstituted C2 to C20 alkenyl group, or a substituted or unsubstituted C6 to C20 aryl group,
M¹ and M³ or M² and M³ are optionally linked to each other to form a ring, and
* is a linking point.

2. The resist underlayer composition as claimed in claim 1, wherein A in Chemical Formula 1 and Chemical Formula 2 is represented by any of Chemical Formula A-1 to Chemical Formula A-5: 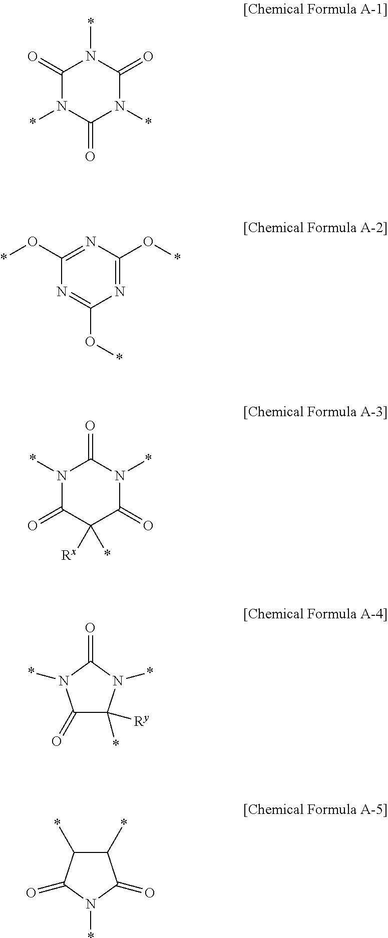
wherein, in Chemical Formula A-3 and Chemical Formula A-4:
R^{x} and R^{y} are each independently hydrogen, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C1 to C10 heteroalkenyl group, a substituted or unsubstituted C1 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, a substituted or unsubstituted C1 to C20 heteroaryl group, or a combination thereof, and
* is a linking point.

3. The resist underlayer composition as claimed in claim 1, wherein A in Chemical Formula 1 is Chemical Formula A-1, L¹ and L² are each independently a single bond, or a substituted or unsubstituted C1 to C10 alkylene group, and X¹ and X² are each independently a single bond:

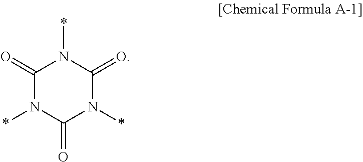 [SMILES: *n1c(=O)n(*)c(=O)n(*)c1=O]

4. The resist underlayer composition as claimed in claim 1, wherein in Chemical Formula 3,
L⁷ and L⁸ are each independently a single bond, or a substituted or unsubstituted C1 to C10 alkylene group,
X⁶ and X⁷ are each independently a single bond, or —(CO)O—, and
R¹ to R³ are each independently hydrogen, deuterium, or a substituted or unsubstituted C1 to C5 alkyl group.

5. The resist underlayer composition as claimed in claim 1, wherein the polymer further includes a structural unit represented by Chemical Formula 5, or a structural unit represented by Chemical Formula 6: 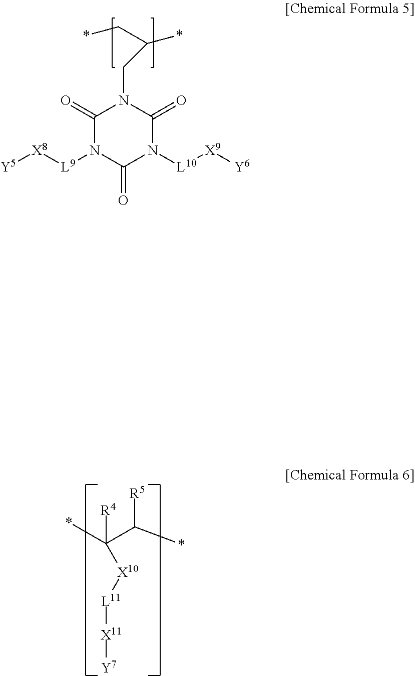
wherein, in Chemical Formula 5 and In Chemical Formula 6,
L⁹ to L¹¹ are each independently a single bond, a substituted or unsubstituted C1 to C10 alkylene group, a substituted or unsubstituted C2 to C10 alkenylene group, a substituted or unsubstituted C2 to C10 alkynylene group, a substituted or unsubstituted C3 to C20 cycloalkylene group, a substituted or unsubstituted C2 to C20 heterocycloalkylene group, a substituted or unsubstituted C6 to C20 arylene group, or a combination thereof,
X⁸ to X¹¹ are each independently a single bond, —O—, —S—, —S(═O)—, —S(═O)₂—, —C(═O)—, —(CO)O—, —O(CO)O—, —C(═O)NH—, —NR^{b}— (wherein, R^{b} is hydrogen, deuterium, or a C1 to C10 alkyl group), or a combination thereof,
Y⁵ to Y⁷ are each independently a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C20 cycloalkyl group, a substituted or unsubstituted C2 to C20 heterocycloalkyl group, or a substituted or unsubstituted C6 to C20 aryl group,
R⁴ and R⁵ are each independently hydrogen, deuterium, or a substituted or unsubstituted C1 to C10 alkyl group, and
* is a linking point.

6. The resist underlayer composition as claimed in claim 5, wherein in Chemical Formula 5, L⁹ and L¹⁰ are each independently a single bond or a substituted or unsubstituted C1 to C10 alkylene group,
X⁸ and X⁹ are each independently a single bond, and
Y⁵ and Y⁶ are each independently a hydroxy group, a substituted or unsubstituted C1 to C10 alkyl group, or a substituted or unsubstituted C2 to C10 alkenyl group.

7. The resist underlayer composition as claimed in claim 5, wherein in Chemical Formula 6,
L¹¹ is a single bond, a substituted or unsubstituted C1 to C10 alkylene group, or a substituted or unsubstituted C6 to C10 arylene group,
X¹⁰ and X¹¹ are each independently a single bond, or —(CO)O—,
Y⁷ is a hydroxy group, a substituted or unsubstituted C1 to C10 alkyl group, a substituted or unsubstituted C2 to C20 heterocycloalkyl group, or a substituted or unsubstituted C6 to C20 aryl group.

8. The resist underlayer composition as claimed in claim 1, wherein the polymer includes any one or more of the structural units represented by Chemical Formula 1-1, Chemical Formula 2-1, and Chemical Formula 3-1 to Chemical Formula 3-8:

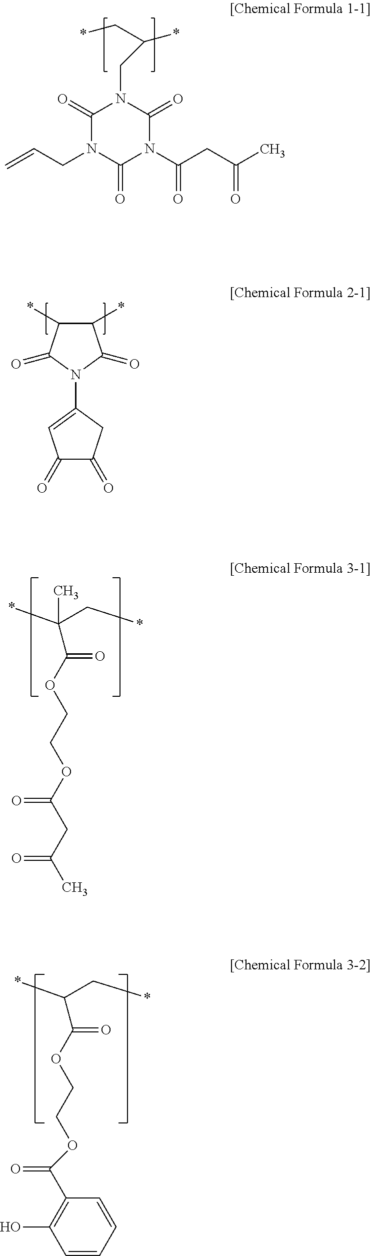

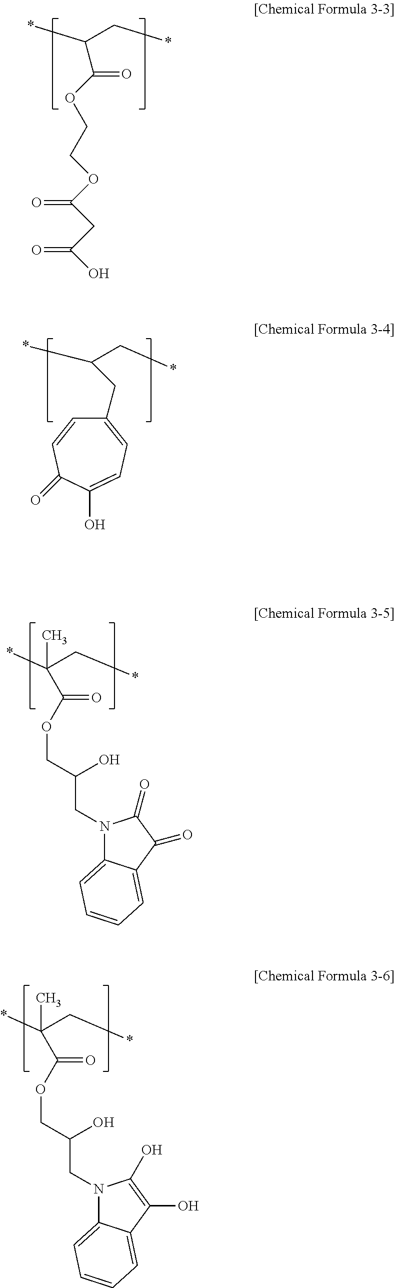

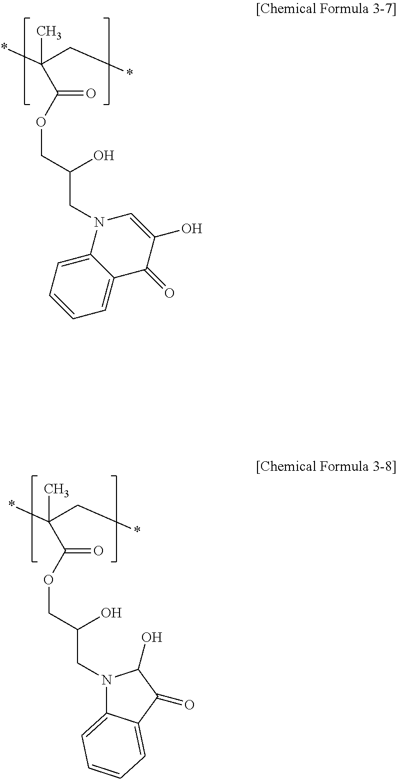

9. The resist underlayer composition as claimed in claim 1, wherein a weight average molecular weight of the polymer is about 1,000 g/mol to about 300,000 g/mol.

10. The resist underlayer composition as claimed in claim 1, wherein the polymer is included in an amount of about 0.1 wt % to about 50 wt % based on a total weight of the resist underlayer composition.

11. The resist underlayer composition as claimed in claim 1, wherein the composition further includes one or more polymers selected from an acrylic resin, an epoxy resin, a novolac-based resin, a glycoluril-based resin, and a melamine-based resin.

12. The resist underlayer composition as claimed in claim 1, wherein the composition further includes an additive of a surfactant, a thermal acid generator, a photoacid generator, a plasticizer, or a combination thereof.

13. A method of forming a pattern comprising
forming an etching target layer on a substrate,
forming a resist underlayer by applying the resist underlayer composition as claimed in claim 1 on the etching target layer,
forming a photoresist pattern on the resist underlayer, and
sequentially etching the resist underlayer and the etching target layer using the photoresist pattern as an etching mask.
